(19) United States
(12) Patent Application Publication
(10) Pub. No.: US 2014/0152355 A1
(43) Pub. Date: Jun. 5, 2014

(54) HIGH-PRECISION ELECTRONIC CLOCK MOVEMENT AND PROCESS FOR ADJUSTING A TIME BASE

(71) Applicant: EM Microelectronic-Marin SA, Marin (CH)

(72) Inventors: Yves GODAT, Cornaux (CH); Nicolas Jeannet, Chambrelien (CH)

(73) Assignee: EM Microelectronic-Marin SA, Marin (CH)

(21) Appl. No.: 14/079,969

(22) Filed: Nov. 14, 2013

(30) Foreign Application Priority Data
Nov. 30, 2012 (EP) 12195077.8

(51) Int. Cl. H03B 19/00

(52) U.S. Cl. CPC H03B 19/00
USPC 327/117

(57) ABSTRACT

Process for adjusting a time base by inhibiting clock pulses supplied by a clock circuit, this adjustment process comprising the following steps:
selecting an inhibition period;
   determining a first number N of clock pulses to be suppressed per inhibition period to adjust over each inhibition period the number of clock pulses activating a frequency divider circuit such that the frequency of the time base comes closest to a reference unit frequency;
selecting a plurality K of sub-periods for each inhibition period;
suppressing in each sub-period a second number N1 of clock pulses corresponding to the result of the integral division of the first number by the number of sub-periods, and
in addition to the suppression of the preceding step, suppressing in each inhibition period a third number N2 of clock pulses corresponding to the remainder of said integral division.

This application claims priority from European Patent Application No. 12195077.8 filed Nov. 30, 2012, the entire disclosure of which is incorporated herein by reference.

### TECHNICAL FIELD

The present invention relates to the field of electronic clock movements, in particular high-precision electronic movements undergoing precision tests to obtain a chronometer certificate awarded by an official body (in Switzerland: the COSC—Official Swiss Chronometer Testing Institute). More generally, the invention relates to time bases comprising a quartz oscillator that are adjusted by inhibiting clock pulses and in particular a process for adjusting such a time base.

### TECHNOLOGICAL BACKGROUND

Electronic clock movements generally comprise a time base that supplies a time signal and a display module that receives this time signal, which is formed from timing pulses. The time base comprises a clock circuit and a frequency divider circuit. The clock circuit is formed by a quartz oscillator and it supplies a clock signal to the frequency divider circuit, wherein this clock signal has a determined clock frequency. The frequency divider circuit is formed by a chain of dividers (usually two) and it outputs a time signal formed from timing pulses generated at a unit frequency.

As it is not possible in an industrial production operation to produce oscillators that all have a reference frequency F0, which would enable timing pulses with a reference unit frequency (in particular 1 Hz) to be obtained, it is provided to produce quartz oscillators with frequencies F that are distributed in a certain frequency range higher than the reference frequency F0. If a base period P0 (in particular 1 minute) is considered, the number of clock pulses at the reference frequency is equal to M0=P0·F0 (F0 is a whole number and it is accepted that P0 is also a whole number of seconds). Quartz oscillators are selected so that the number of pulses X0 (real number) that they generate in the period P0 lies between M0 and M0+N0max (i.e. M0<X0<M0+N0max). To best adjust the time signal generated by the time base, it is known to connect an inhibition circuit to this time base that supplies as input to the frequency divider circuit an inhibition signal that causes a number N0 of clock pulses per inhibition period P0 to be suppressed to adjust the number of clock pulses activating the frequency divider circuit over each inhibition period P0. The number N0 is a positive whole number. It is determined for each clock circuit such that the frequency divider circuit is activated over the period P0 X0−N0 number of times, which is rounded to the whole number M0 (i.e. M0-½<X0−N0<=M0+½). Thus, the precision obtained for the clock movement is equal to (½)/M0=½M0.

To increase the precision of the clock movement, it is possible to increase the inhibition period P by a factor Y in relation to P0, i.e. P=Y·P0 where Y>1. Over this period P the number of clock pulses M at the reference frequency is equal to Y·M0 (i.e. M=Y·M0), while the number X of clock pulses at frequency F generated by a given quartz oscillator is equal to Y·X0 (i.e. X=Y·X0). It will be noted that in the case of quartz oscillators selected according to the abovementioned criterion, the maximum number of clock pulses Nmax to be inhibited over the period P is equal to Y·N0max (i.e. Nmax=Y·N0max). Again, the number N of clock pulses to be inhibited is determined for each oscillator by the mathematical equation:

M−½<X−N<=M+½. Thus, the precision obtained by the inhibition is equal to (½)/M=(½)/(Y·M0)=(1/Y)·(½M0). It is thus observed that the precision over an inhibition period increases by a factor Y when the inhibition period is increased by this factor Y. It will be noted that this precision corresponds to the average precision of the time base that gives the drift of this time base over time.

However, increasing the inhibition period from P0 to P poses a problem to be explained below, since the absolute maximum error EAmax between two measurements of the time supplied by the time base increases proportionally to Y, because the inhibition of the N clock pulses per inhibition period is conducted in total at time intervals corresponding to the inhibition period. Moreover, the classic definition of inhibition period comes from this procedure. Thus,

EAmax(P)=Nmax/F=Y·N0max/F=Y·EAmax(P0)

This is shown in FIG. 2 for an inhibition period P of eight minutes (8 min). If P0 is equal to one minute (1 min), the absolute maximum error EAmax is proportional to the inhibition period and this maximum absolute error within the period P is eight times higher than the corresponding error for a base inhibition period P0. The instantaneous absolute error does not pose any problem for the running of the clock movement and it becomes negligible in the case of long periods, but it does pose a significant problem during precision tests on the time base or the clock movement comprising such a time base. Hence, when the precision is increased by increasing the inhibition period, it cannot be verified over a short period, so that it is not possible to obtain a highly precise chronometer certificate from a certification body, in particular the COSC in Switzerland. The tests are conducted, for example, over periods of about 24 hours and in an asynchronous manner in relation to the inhibition periods P. In other words, the test period is not determined to be equal to a multiple of the inhibition period, so that it is possible to practically measure the maximum absolute error over this test period. The resulting relative error is relatively high since the test period is relatively short. The measurement of the real precision of the clock movement cannot therefore be established correctly by a certification body.

### SUMMARY OF THE INVENTION

The aim of the present invention is to resolve the problem of the aforementioned prior art, i.e. to allow an increase in the precision of an electronic clock movement by assuring that it successively undergoes certification tests to establish the high precision of this clock movement.

The present invention relates to an electronic clock movement comprising a time base arranged to supply a time signal formed from timing pulses generated at a unit frequency, wherein this time base comprises:
a clock circuit that supplies clock pulses with a determined clock frequency;
a frequency divider circuit that receives the clock pulses at a first input and outputs the time signal;
an inhibition circuit that supplies an inhibition signal to a second input of the frequency divider circuit, wherein this inhibition circuit is arranged so that the inhibition signal causes a first number N of clock pulses per inhibition period P to be suppressed in order to adjust the number of clock pulses activating the frequency divider circuit over each inhibition period such that said unit frequency comes closest to a reference unit frequency.

In accordance with industrial practice, the clock frequency of this electronic clock movement is provided in a certain frequency range higher than a reference frequency, which would allow a reference unit frequency to be obtained at the output of the frequency divider circuit in the absence of inhibition.

According to the invention each inhibition period is divided into a plurality K of sub-periods and the inhibition circuit, for causing the suppression of N clock pulses, is arranged so as to suppress in each sub-period a second number of clock pulses corresponding to the result of the integral division of the first number by the number of sub-periods INT[N/K] and additionally in each inhibition period a third number of clock pulses corresponding to the remainder of said integral division (N modulo K).

The invention also relates to a process for adjusting a time base corresponding to the algorithm implemented in the clock movement according to the invention.

Because of the features of the invention it is possible to increase the precision of the clock movement by increasing the inhibition period P and to reduce the absolute error so that it corresponds substantially to that of an inhibition period that is shorter by a factor K.

### BRIEF DESCRIPTION OF THE DRAWINGS

The invention shall be described in detail on the basis of attached drawings given by way of non-restrictive example:

FIG. 1 schematically shows functional blocks of the electronic clock movement according to the invention;

FIG. 2 already described—is a graph giving the absolute time error over time for a movement of the prior art with an inhibition period of eight minutes (8 min);

FIG. 3 is a graph similar to that of FIG. 2 giving the absolute time error over time for an electronic clock movement according to the invention also with an inhibition period of eight minutes (8 min); and

FIG. 4 shows a variant of the inhibition process according to FIG. 3.

### DETAILED DESCRIPTION OF THE INVENTION

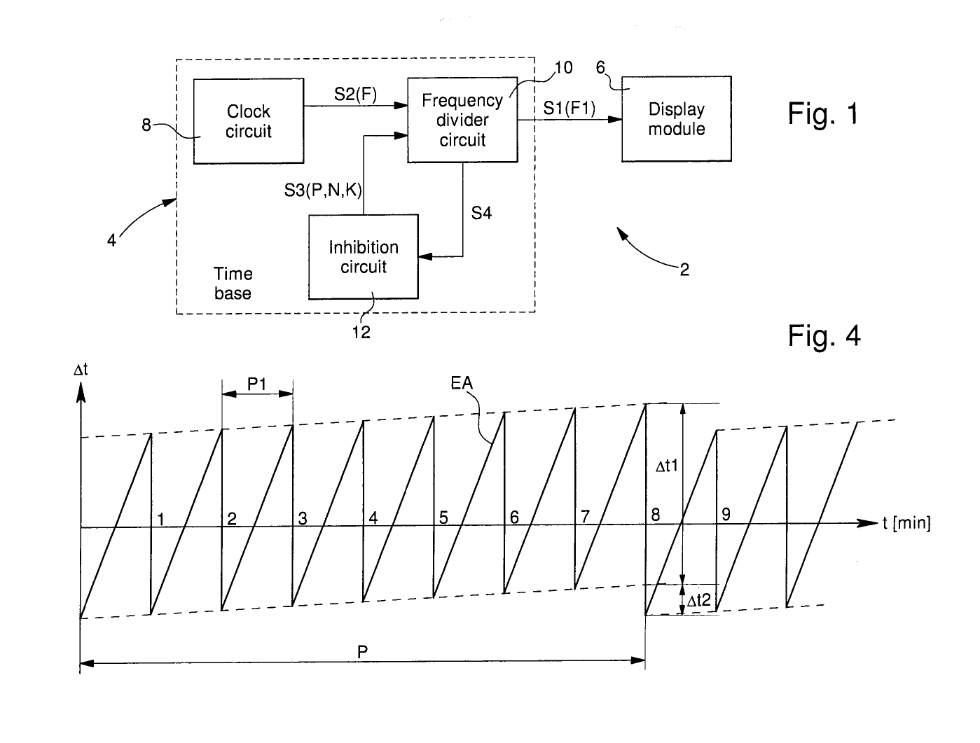

FIG. 1 schematically shows an electronic clock movement 2 comprising a time base 4 arranged to supply a time signal S1 formed from time pulses generated at a unit frequency F1. The time base comprises:
a clock circuit 8 that supplies a clock pulse S2 formed from clock pulses generated at a determined clock frequency F;
a frequency divider circuit 10 that receives the clock pulses of the clock signal S2 at a first input and outputs the time signal S1;
an inhibition circuit 12 that supplies an inhibition signal S3 to a second input of the frequency divider circuit 10.

To synchronise the inhibition circuit 1 with the clock circuit and also to manage the periodic transmission of the inhibition signal, this inhibition circuit is connected to the frequency divider circuit 10, which supplies it with a control signal S4.

As already explained above, the clock frequency F is provided in a certain frequency range higher than a reference frequency F0 which, in the absence of inhibition, would allow a reference unit frequency output from the frequency divider circuit to be obtained. The reference unit frequency is generally 1 Hz (period of 1 s).

According to the invention the adjustment process conducted in the clock movement according to the invention comprises the following steps:
selecting an inhibition period P greater than one minute;
determining a first number N of clock pulses to be suppressed per inhibition period P to adjust over each inhibition period P the number of clock pulses activating the frequency divider circuit 10 such that the unit frequency F1 comes closest to the abovementioned reference unit frequency;
selecting a plurality K of sub-periods P1 for each inhibition period P;
suppressing in each sub-period P1 a second number N1 of clock pulses corresponding to the result of the integral division of the first number N of clock pulses by the number K of sub-periods (N1=INT[N/K]), and
in addition to the suppression of the preceding step, suppressing in each inhibition period P a third number N2 of clock pulses corresponding to the remainder of the integral division of the first number N of clock pulses by the number K of sub-periods (N2=N modulo K).

Thus, over each inhibition period P the first number N is actually suppressed to enable the maximum precision to be obtained for this inhibition period. In fact N=N1+N2.

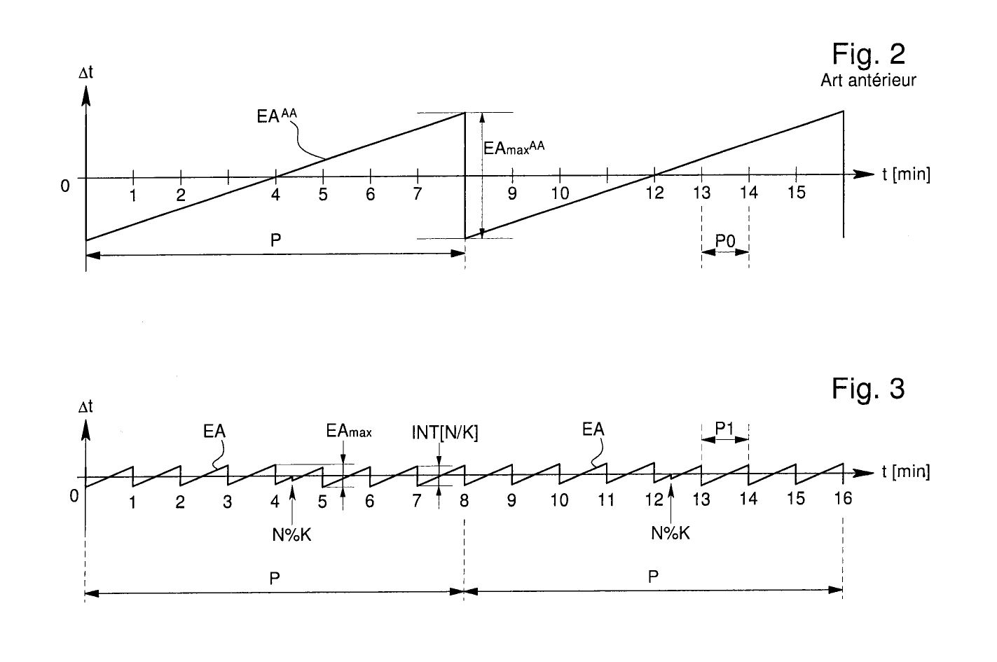

FIG. 3 shows the benefit of the process for adjusting the time base 4 according to the present invention. In the prior art it is usual to provide an inhibition period P0 equal to one minute (P0=1 min). A longer inhibition period P, e.g. of eight minutes (P=8 min), can be used to increase the precision, as in the variant of the prior art shown in FIG. 2. Taking the specific case where the adjustment of the time base by inhibiting clock pulses over the period P allows the reference unit frequency to be obtained exactly, the instantaneous absolute error EA^{AA} varies with a gradient given by (N/P)/F, where N is the number of clock pulses to be suppressed per period P and F is the clock frequency. Thus, in the prior art the maximum absolute error EA^{AA} over a period P (between the start and the end of the period) is equal to N/F. In the case where N=Nmax, a maximum absolute error equal to Nmax/F over period P is obtained. In the above specific case, it will be noted that N=Y·N0, where N0 is the number of pulses to be suppressed over a base period P0=P/Y. In general, Nmax=Y·N0max.

FIG. 3 gives the absolute error EA with the adjustment process according to the invention for an inhibition period P corresponding to that of the case of the prior art of FIG. 2. Taking K=8 and therefore a sub-period of P1=1 min, the maximum absolute error EAmax between any two instants of a period P is greatly reduced. It is essentially given by the following equality and inequality:

EAmax=(INT[N/K]+N modulo K)/F

EAmax<(INT[N/K]+K)/F

It will be observed that in FIG. 3 N modulo K is indicated as N % K. By way of example, P1 is chosen as equal to the base period P0, but this is a particular case that is not at all restrictive. In particular, K=4 and P1=2 min can be taken for a period of P=8 minutes, or K=16 and P1=30 seconds (30 s).

In the above specific case EAmax=INT[N/K]=N0 and EAmax corresponds to the maximum absolute error between any two instants over time. Let us take a numerical example to illustrate the general case, i.e. P=8 min, K=8 and N=245. Thus, in the case of the prior art (FIG. 2) the maximum absolute error EAmax^{AA}=245/F. In the case of the present invention the sub-period P1=1 min, INT[N/K]=30 and N modulo K=5. Thus, the maximum absolute error EAmax=(30+5)/F=35/F. According to the previously given inequality, EAmax<(INT[N/K]+K)/F=38/F. It can therefore be seen that in the worst case the maximum absolute error is reduced by at least a factor of six.

In FIG. 3 the correction of the remainder of the integral division over the period P (N modulo K, given as N % K) is conducted within a single sub-period P1 (sub-periods No 5, 13, . . . 5+nK, . . . ) in each inhibition period P, whereas the correction of INT[N/K] clock pulses is conducted at the end or at the beginning of each sub-period P1. FIG. 4 shows in more detail a variant of the adjustment process according to the invention where the correction of the remainder of the integral division N modulo K over the period P is conducted together with a correction of INT[N/K] clock pulses at the end or at the beginning of a sub-period P1. In the variant of FIG. 4 Δt1=(INT[N/K])/F and Δt2=(N modulo K)/F. An example has been taken where Δt2 is not zero and is about equal to a sixth of Δt1, as in the numerical example given above. As the correction Δt1 in each sub-period P1 is relatively inexact since N modulo K is not zero, it is evident that there is a drift during the course of each inhibition period P defined by the dotted lines. This drift is compensated at the end of the inhibition period P so that the average frequency of the time base is identical to that obtained in an embodiment of the prior art with the same inhibition period P. As mentioned above, the maximum absolute error EAmax=Δt1+Δt2.

Given that work is generally conducted with binary registers in a digital circuit, K=2ⁿ is preferably selected, wherein n is a whole number higher than one (n>1). The number N has a maximum Nmax given by the production tolerance of quartz oscillators. N is a whole number recorded in binary form in a memory register. For example, Nmax=1023. As 2¹⁰=1024, the memory register thus comprises 10 bits. In general, 2ⁿ<Nmax<2^{m} is applied, wherein m is by definition greater than n in the framework of the invention (m>n). Thus, the two numbers of pulses to be suppressed that must be determined for implementation of the adjustment process of the time base, i.e. INT[N/K] and N modulo K, are easily obtained. In fact, on the one hand, INT[N/K] corresponds to the binary number obtained by taking the m-n first bits of the memory register, which amounts to shifting the binary number in the memory register of m-n bits to the right. On the other hand, N modulo K is given by the n last bits of the memory register.

What is claimed is:

1. An electronic clock movement comprising a time base arranged to supply a time signal formed from timing pulses generated at a unit frequency, wherein this time base comprises:
a clock circuit that supplies clock pulses with a determined clock frequency;
a frequency divider circuit that receives said clock pulses at a first input and outputs said time signal;
an inhibition circuit that supplies an inhibition signal to a second input of said frequency divider circuit, wherein this inhibition circuit is arranged so that the inhibition signal causes a first number N of clock pulses per inhibition period to be suppressed in order to adjust the number of clock pulses activating said frequency divider circuit over each inhibition period such that said unit frequency comes closest to a reference unit frequency;
wherein said clock frequency is provided in a certain frequency range higher than a reference frequency, which would allow a reference unit frequency to be obtained at the output of the frequency divider circuit in the absence of inhibition,
wherein each inhibition period is divided into a plurality K of sub-periods, and wherein the inhibition circuit, for causing the suppression of N clock pulses, is arranged so as to suppress in each sub-period a second number N1 of clock pulses corresponding to the result of the integral division of the first number by the number of sub-periods (N1=INT[N/K]) and additionally in each inhibition period a third number N2 of clock pulses equal to the remainder of said integral division (N2=N modulo K).

2. The electronic clock movement according to claim 1, wherein the number K of sub-periods is equal to an integral power of two, i.e. K=2ⁿ, wherein n is a whole number higher than zero (n>0) and the number K is lower than a maximum number of clock pulses to be suppressed per inhibition period.

3. The electronic clock movement according to claim 1, wherein the whole number n is higher than two (n>2).

4. The electronic clock movement according claim 1, wherein the inhibition period is greater than or equal to eight minutes.

5. A process for adjusting a time base arranged to supply a time signal formed from timing pulses generated at a unit frequency, wherein this time base comprises:
a clock circuit that supplies clock pulses with a determined clock frequency;
a frequency divider circuit that receives said clock pulses at a first input and outputs the time signal;
an inhibition circuit that supplies an inhibition signal to a second input of said frequency divider circuit,
wherein said clock frequency is provided in a certain frequency range higher than a reference frequency, which would allow a reference unit frequency to be obtained at the output of the frequency divider circuit in the absence of inhibition,
this adjustment process comprising the following steps:
selecting an inhibition period greater than one minute;
determining a first number N of clock pulses to be suppressed per inhibition period to adjust over each inhibition period the number of clock pulses activating said frequency divider circuit such that said unit frequency comes closest to said reference unit frequency;
selecting a plurality K of sub-periods for each inhibition period;
suppressing in each sub-period a second number N1 of clock pulses corresponding to the result of the integral division of the first number by the number of sub-periods (N1=INT[N/K]), and
in addition to the suppression of the preceding step, suppressing in each inhibition period a third number N2 of clock pulses corresponding to the remainder of said integral division (N2=N modulo K).

6. The adjustment process according to claim 5, wherein the number K of sub-periods is equal to an integral power of two, i.e. K=2ⁿ, wherein n is a whole number higher than zero (n>0) and the number K is lower than a maximum number of clock pulses to be suppressed per inhibition period.

7. An adjustment process according to claim 5, wherein the whole number n is higher than two (n>2).

8. An adjustment process according to claim 5, wherein the inhibition period is greater than or equal to eight minutes.
